(19) United States
(12) Patent Application Publication
(10) Pub. No.: US 2025/0232968 A1
(43) Pub. Date: Jul. 17, 2025

(54) Resonant Frequency Shift as Etch Stop of Gate Oxide of MOSFET Transistor

(71) Applicant: KING FAISAL UNIVERSITY, Al-Ahsa (SA)

(72) Inventor: HESHAM MOHAMMED ENSHASY, ALHasaa (SA)

(21) Appl. No.: 18/680,425

(22) Filed: May 31, 2024

Related U.S. Application Data
(62) Division of application No. 18/414,436, filed on Jan. 16, 2024, now Pat. No. 12,020,915.

(51) Int. Cl. H01J 37/32; H01L 21/66

(52) U.S. Cl. CPC H01J 37/32963; H01L 22/26; H01J 2237/24592; H01J 2237/334

(57) ABSTRACT

An etch process performed during semiconductor processing is monitored using a resonant structure on a surface of a wafer, formed on the surface of a wafer as a resonant cavity. A resonance sensor is positioned over the wafer within a plasma etch chamber so as to establish a resonance with the resonant structure. A resonant frequency of the resonant structure is sensed through the resonant structure and shifts in the resonant frequency are thereby detected during an etch process as a measurement of the etch process. The etch process is controlled in accordance with the shift in the resonant frequency.

### CROSS-REFERENCE TO RELATED APPLICATION

This application is a divisional of U.S. patent application Ser. No. 18/414,436, filed on Jan. 16, 2024, the entire contents of which are incorporated herein by reference.

### BACKGROUND

### Technical Field

The present disclosure relates to semiconductor processing using a sensor that exhibits the required sensitivity for monitoring a critical process and it relies on a resonant cavity filter as its core component.

### Background Art

Utilization of a resonant frequency filter for the analysis or precise control of the etching process within the wafer processing chamber, and the use of acoustic signals generated within the wafer processing chamber for the control of wafer etch processing has been proposed or implemented. Various approaches include control of an etch process being regulated by a resonant filter. Another approach uses a surface acoustic wave sensor, in which the surface acoustic wave sensor utilizes the acoustic signal within the wafer processing chamber.

A resonant filter can be used to regulate etch processing. For example, WO2019040843A1, to Rinzan, et al., discloses etch processing regulated by the resonant filter, in which the resonant filter gauges changes in resonant frequency by detection of a frequency shift and alterations in acoustic impedance, thereby controlling the etching process.

WO2021178464A1, to Lapidot, et al., discloses controlling an etching process through the utilization of both a QCM (Quartz Crystal Microbalance) sensor and a surface acoustic wave sensor. The real-time etching process is calculated and/or controlled by combining the data from these two sensors. The QCM sensor relies on the reflected resonance signal, while the surface acoustic wave sensor utilizes the acoustic signal within the wafer processing chamber.

### SUMMARY

Monitoring an etch process performed during semiconductor processing is performed using a resonant structure on a surface of a wafer. A resonant structure is formed on a surface of a wafer to form a resonant cavity. A resonance sensor is positioned over the wafer so as to establish a resonance with the resonant structure. A resonant frequency of the resonant structure is sensed through the resonant structure and shifts in the resonant frequency are thereby detected during an etch process as a measurement of the etch process. The etch process is controlled in accordance with the shift in the resonant frequency.

In one configuration, the etch process comprises a plasma etch process.

### BRIEF DESCRIPTION OF THE DRAWINGS

FIG. 1 is a schematic diagram showing a resonant structure in a plan view, which is used as the active part of a resonant circuit.

FIG. 2 is a schematic diagram showing a cross-sectional view of a resonant cavity formed on a substrate, in which a controlled etching process is used to etch aluminum fingers of a resonant cavity formed on the substrate.

FIG. 3 is a schematic diagram showing a configuration for performing plasma etch using the resonant cavity of FIGS. 1 and 2.

### DETAILED DESCRIPTION

### Overview

It is desired, when using resonant measurements for semiconductor processing, such as implementing semiconductor etch processes, to provide a single sensor circuit positioned over the wafer processing chamber, capable of measuring both resonant frequency shift and acoustic signal variation. It is further desired, in a plasma etch process, to control of the plasma etching process based on the measured variations in both frequency shift and acoustic signals.

As used herein, “semiconductor” and “semiconductor processing” is intended to be inclusive of operations performed on semiconductor wafers, quartz wafers, piezoelectric crystal material, materials used to construct solar cells and other materials subject to semiconductor processing such as plasma etch.

In the realm of MOSFET transistors, precise control over the ultra-thin oxide layer is of paramount importance. The gate oxide, typically measured in tens of angstroms, necessitates a level of control down to a monolayer thickness for optimal device performance. According to the present disclosure, a sensor that exhibits the required sensitivity is used for monitoring this critical process. This sensor relies on a resonant cavity filter as its core component, and the resonant cavity filter operates by allowing a propagating wave to reflect multiple times. The resonant cavity filter is incorporated in the etching system where the sensor gets etched as the gate oxide of the MOSFET transistor wafer gets etched.

Maximum reflection is achieved when the following formula is satisfied:

$$F = \frac{V}{2 λ} \qquad ( Eqn . 1 )$$

where F is the resonant frequency of the cavity, V is the acoustic wave at the surface through reflective structures, and λ is the reflective grating period.

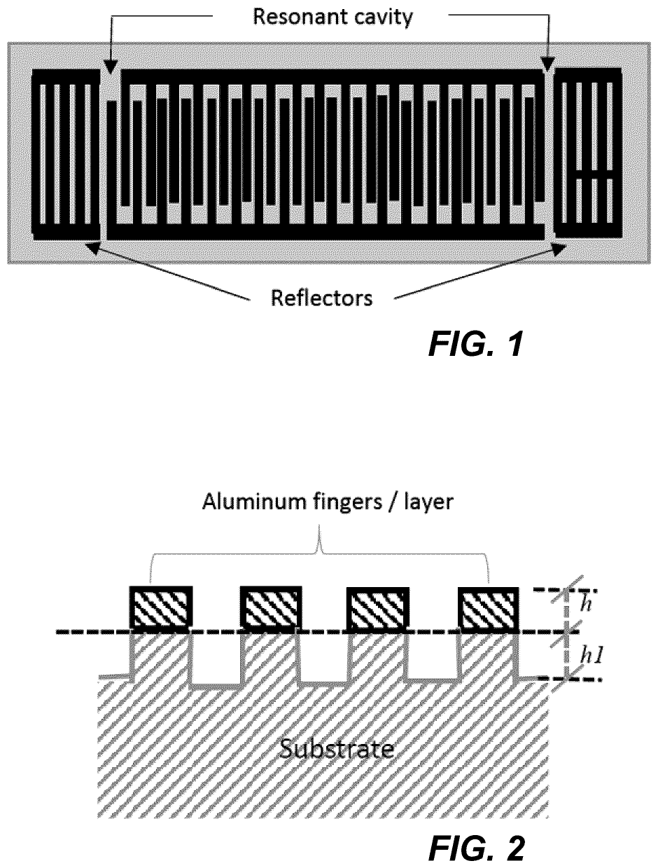

FIG. 1 is a schematic diagram showing a resonant structure in a plan view, which is used as the active part of a resonant circuit. The resonant structure, which during an etch process is used as part of the resonant circuit, includes a resonant sensor located in an etch chamber such as a plasma etch chamber. These devices can work in a superior manner to their counterparts at the UHF level because they can be made efficient and frequency selective. By depositing the metal film on a piezoelectric substrate in the form of gratings, and controlling the thickness of the gratings and the cavity length and depth between them, only a very narrow frequency band wave can pass through the device. In more detail, the length of the cavity should equal one half of the wave-length.

The resonant structure is fabricated from a thin metal layer, often aluminum, deposited via sputtering, evaporation or vapor deposition onto a substrate made of piezoelectric crystal material, such as quartz. The deposited metal layer is deposited through a photomask or deposited or etched through a photomask to take the form of two sets of interlocked fingers or gratings, electrically insulated from each other. The precise dimensions of these gratings, along with the cavity length and depth between them, enable the passage of a narrow frequency band wave through the device. The center frequency (CF) of the resonance structure is influenced by the weight of the metal layer atop the piezoelectric crystal. This approach capitalizes on the nearly identical densities of aluminum and the substrate:
Quartz=2.65 g/cm³
Aluminum=2.7 g/cm³

The use of an aluminum conductive layer is given by way of non-limiting example, as the conductive layer may be formed of any suitable metal or other conductor.

FIG. 2 is a schematic diagram showing a cross-sectional view of a resonant cavity formed on a substrate, in which a controlled etching process is used to etch aluminum into fingers of a resonant cavity formed on the substrate. In a controlled etching process, such as groove etching h₁, effectively mimics an increase in the thickness of the aluminum layer.

In this approach, the aluminum electrodes function as a mask, guiding the etching process applied to the quartz or silicon substrate. Since the etchant that is used for the MOSFET gate oxide is the same etchant for the quartz material, a substantial shift in the frequency is anticipated with each monolayer removal of quartz material. This shift can be directly correlated with the depth of gate oxide etching, providing a robust and precise means of monitoring the process. To calculate the frequency shift ΔF, the following formula is used in practice:

$$\frac{Δ F}{F} = ( \frac{- h}{{λ}^{2}} ) ( 0.4 d + 7 h + 3.5 {h}_{1} \qquad ( Eqn . 2 )$$

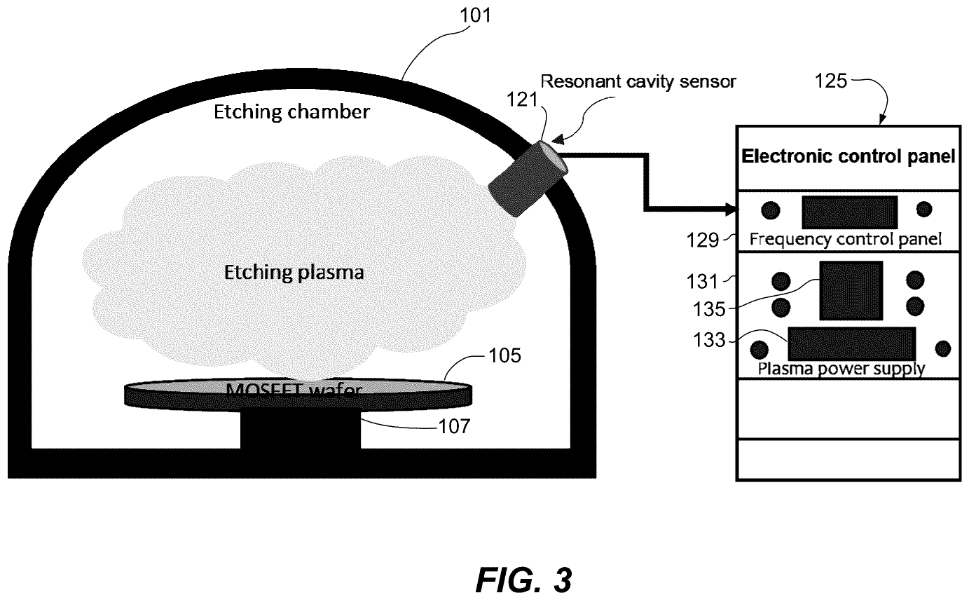

FIG. 3 is a schematic diagram showing a configuration for performing plasma etch using the resonant cavity of FIGS. 1 and 2. Depicted are plasma etch chamber 101, in which semiconductor wafer 105 is supported on cathode 107 for a plasma etch process. The arrangements of the plasma gas inlet and anode are conventional and not shown for purposes of clarity, but are known to skilled artisans. Also shown is resonant cavity sensor 121, which is a transceiver operating in a predetermined range of resonant frequencies. Electronic control unit 125 includes frequency control unit 129 and has a power supply that may be integrated with plasma power supply 131. In the non-limiting example shown, electronic control unit 125 includes frequency control unit 129, and plasma power supply 131. Plasma power supply 131 includes plasma power supply output circuit 133 and plasma power supply controller 135, which functions as a process control circuit. In the non-limiting example, the plasma power supply controller 135 is linked with frequency control unit 129, to receive indications of the resonant frequency as detected by resonant cavity sensor 121 and provide power to frequency control unit 129, which is connected to resonant cavity sensor 121.

The details of the connection and control circuits are given as non-limiting examples, as the functional operation is to control the plasma in accordance with resonant frequency, which is indicative of the depth of the plasma etch. Frequency control unit 129 is used to transmit and receive signals to determine the depth of the plasma etch. FIG. 3 shows the resonant cavity filter incorporated in the etching system, in which the sensor is etched, by way of non-limiting example as the gate oxide of a MOSFET transistor wafer. A scaling factor is needed to correlate the etch rate of the MOSFET gate oxide to the etch rate to sensor cell, as is well known to skilled artisans. As the etching process starts, h will decrease where each monolayer that will be etched will shift the frequency in a measurable manner according to equation (2). This process will translate as a monolayer control on the gate oxide etch of the MOSFET wafer.

### Closing Statement

It will be understood that many additional changes in the details, materials, steps and arrangement of parts, which have been herein described and illustrated to explain the nature of the subject matter, may be made by those skilled in the art within the principle and scope of the invention as expressed in the appended claims.

1. An etch apparatus having a capability of monitoring an etch process performed during semiconductor processing, comprising:
a plasma etch chamber;
a resonant cavity sensor positioned within the plasma etch chamber so as to establish a resonance with a resonant structure on a wafer under an etch process in the plasma etch chamber;
an electronic control unit operatively connected to the resonant cavity sensor and capable of using the resonant cavity sensor to determine a resonant frequency of the resonant structure on the wafer; and
a process control circuit that includes circuitry to control the etch process in the plasma etch chamber in response to a resonant frequency of the resonant structure on the wafer corresponding to a predetermined etch,
wherein the resonant structure comprises a pair of interlocked fingers or gratings, the pair of interlocked fingers or grating being electrically insulated from one another, and
wherein the pair of interlocked fingers or gratings is disposed directly on the wafer.

2. (canceled)

3. The etch apparatus of claim 1, further comprising a first reflector disposed on a first side of the resonant structure.

4. The etch apparatus of claim 3, further comprising a second reflector disposed on a second side of the resonant structure, opposite to the first reflector.

5. The etch apparatus of claim 1, wherein the pair of interlocked fingers or gratings is made of a metal.

6. The etch apparatus of claim 5, wherein the metal is aluminum.
